(19) United States
(12) Patent Application Publication
(10) Pub. No.: US 2020/0243636 A1
(43) Pub. Date: Jul. 30, 2020

(54) DISPLAY PANEL AND DISPLAY DEVICE

(71) Applicant: Wuhan China Star Optoelectronics Semiconductor Display Technology Co., Ltd., Wuhan (CN)

(72) Inventor: Sisi ZHOU, Wuhan (CN)

(73) Assignee: Wuhan China Star Optoelectronics Semiconductor Display Technology Co., Ltd., Wuhan (CN)

(21) Appl. No.: 16/488,605

(22) PCT Filed: Apr. 3, 2019
(86) PCT No.: PCT/CN2019/081166

§ 371 Date: Aug. 26, 2019

(30) Foreign Application Priority Data
Jan. 29, 2019 (CN) 201910088124.2

(51) Int. Cl. H01L 27/32; H01L 51/52; H05K 1/18

(52) U.S. Cl. CPC H01L 27/3276; H05K 2201/10128; H05K 1/189; H01L 51/5253

(57) ABSTRACT

The present disclosure provides a display panel and a display device. There has a plurality of columns of through holes are disposed on the signal line of the display panel, and the through holes in neighboring two columns are staggered with each other. Reducing the number of the segments of the signal line can decrease the impedance of the signal line of the signal line layer of the display panel effectively and lower the delay of the signal transmission through the signal line of the signal line layer, thereby improving the display quality of the display panel.

### FIELD OF THE INVENTION

The present disclosure is related to the field of display technology, and specifically to a display panel and a display device.

### BACKGROUND OF THE INVENTION

Because of high contrast, wide color gamut, low power consumption, and foldability of the Active Matrix Organic Light Emitting Diode (AMOLED) display panel, the AMOLED are becoming a new generation display technology. Compared with the Liquid Crystal Display (LCD), one of the great advantages of the AMOLED is that it can be applied to flexible display panels. In particular, the lower frame portion of the panel can be bent to the back of the panel through the pad bending technology, thus achieving the purpose of reducing the size of the frame portion of the screen.

The signal line for the data signal transmission is likely to crack or even break during the bending process and makes signal line unable to transmit data signal. To improve the problem that the signal line breaks easily during the bending process and to enable the signal lines to be bent into a curved shape, holes are defined in the signal lines to reduce the stress of the signal lines. In the prior art, 2-100 signal lines on both sides of the display panel which have the similar portions requiring to be bent. Excessive segmentation of the signal line by the too many holes defined therein causes the width of the bent portion of the signal line to become smaller, thus increasing the impedance of the signal line, thereby making the delay of the signal transmission through the signal line become longer.

In summary, there exists a long delay of signal transmission in the bent portion of the signal line of the prior display panel, which causes the poor display quality of the display panel. Therefore, it is necessary to provide a display panel and a display device to solve the problem.

### SUMMARY OF THE INVENTION

In the prior art, 2-100 signal lines on both sides of the display panel which have the similar portions requiring to be bent. Excessive segmentation of the signal line by the too many holes defined therein causes the width of the bent portion of the signal line to become smaller, thus increasing the impedance of the signal line, thereby making the delay of the signal transmission through the signal line become longer.

The present disclosure provides a display panel and a display device to solve the problem that the poor display quality of the display panel due to the long delay of the prior signal line.

The present disclosure provides a display panel, comprising:

a substrate;

a display layer, the display layer disposed on the substrate; and

a signal line layer, the signal line layer disposed on the substrate;

wherein the signal line layer comprises a plurality of spaced signal lines, each of the signal lines has a plurality of columns of through holes, and the through holes in neighboring two columns are staggered with each other.

According to an embodiment of the present disclosure, wherein a shape of each of the through holes is a rectangle, a rhombus, or a circle.

According to an embodiment of the present disclosure, wherein material of the signal line layer is metal.

According to an embodiment of the present disclosure, wherein the display panel comprises a buffer protection layer and a support layer;

wherein the substrate and the signal line layer are bent to the back of the display layer;

wherein the support layer is disposed on a side of the substrate away from the display layer; and

wherein the buffer protection layer is disposed between the support layer and the side of the substrate near the display layer.

According to an embodiment of the present disclosure, wherein the display panel comprises a first organic protective layer and a second organic protective layer;

wherein the first organic protective layer is disposed between the substrate and the signal line layer; and

wherein the second organic protective layer is disposed on the signal line layer.

According to an embodiment of the present disclosure, wherein the display panel comprises a barrier layer, and the barrier layer is disposed between the substrate and the first organic protective layer.

According to an embodiment of the present disclosure, wherein the display panel comprises a driver circuit chip and a flexible circuit board, and the driver circuit chip and the flexible circuit board are disposed on the signal line layer.

The present disclosure provides a display device, comprising:

a display panel, the display panel comprising a substrate, a display layer, and a signal line layer;

wherein the display layer and the signal line layer are disposed on the substrate; and

wherein the signal line layer comprises a plurality of spaced signal lines, each of the signal lines has a plurality of columns of through holes, and the through holes in neighboring two columns are staggered with each other.

According to an embodiment of the present disclosure, wherein material of the signal line layer is a metal.

According to an embodiment of the present disclosure, wherein a shape of each of the through holes is a rectangle, a rhombus, or a circle.

According to an embodiment of the present disclosure, wherein the display panel comprises a buffer protection layer and a support layer;

wherein the substrate and the signal line layer are bent to the back of the display layer;

wherein the support layer is disposed on a side of the substrate away from the display layer; and

wherein the buffer protection layer is disposed between the support layer and the side of the substrate near the display layer.

According to an embodiment of the present disclosure, wherein the display panel comprises a first organic protective layer and a second organic protective layer;

wherein the first organic protective layer is disposed between the substrate and the signal line layer; and

wherein the second organic protective layer is disposed on the signal line layer.

According to an embodiment of the present disclosure, wherein the display panel comprises a barrier layer, and the barrier layer is disposed between the substrate and the first organic protective layer.

According to an embodiment of the present disclosure, wherein the display panel comprises a driver circuit chip and a flexible circuit board, and the driver circuit chip and the flexible circuit board are disposed on the signal line layer.

The present disclosure further provides a display device, comprising:

a display panel, the display panel comprising a substrate, a display layer, and a signal line layer;

wherein the display layer and the signal line layer are disposed on the substrate;

wherein the support layer is disposed on a side of the substrate away from the display layer;

wherein the substrate and the signal line layer are bent to the back of the display layer;

wherein material of the signal line layer is metal; and

wherein the signal line layer comprises a plurality of spaced signal lines, each of the signal lines has a plurality of columns of through holes, and the through holes in neighboring two columns are staggered with each other.

According to an embodiment of the present disclosure, wherein a shape of each of the through holes is a rectangle, a rhombus, or a circle.

According to an embodiment of the present disclosure, wherein the display panel comprises a first organic protective layer and a second organic protective layer;

wherein the first organic protective layer is disposed between the substrate and the signal line layer; and

wherein the second organic protective layer is disposed on the signal line layer.

According to an embodiment of the present disclosure, wherein the display panel comprises a barrier layer, and the barrier layer is disposed between the substrate and the first organic protective layer.

According to an embodiment of the present disclosure, wherein the display panel comprises a driver circuit chip and a flexible circuit board, and the driver circuit chip and the flexible circuit board are disposed on the signal line layer.

The beneficial effects of the present disclosure: present embodiments of the disclosure show that there has a plurality of columns of through holes are disposed on the signal line of the signal line layer of the display panel, and the through holes in neighboring two columns are staggered with each other. Reducing the number of the segments of the signal line can decrease the impedance of the signal line of the signal line layer of the display panel and lower the delay of the signal transmission through the signal line of the signal line layer, thereby improving the display quality of the display panel.

### DESCRIPTION OF DRAWINGS

In order to describe technical solutions in the present disclosure clearly, drawings to be used in the description of embodiments will be described briefly below. Apparently, drawings described below are only for some embodiments of the present disclosure, and other drawings may be obtained by those skilled in the art based on these drawings without creative efforts.

FIG. 1 is a structural diagram of the display panel provided by the present disclosure; and

FIG. 2 is a structural diagram of the signal line layer provided by the present disclosure.

### DETAILED DESCRIPTION

Examples are described below with reference to the appended drawings, to exemplify a particular embodiment of the invention each of the embodiments of the present embodiment. Directional terms mentioned in the present disclosure, such as “upper”, “lower”, “front”, “rear”, “left”, “right”, “inside”, “outside”, “side”, etc., only reference to the accompanying drawings direction. Thus, the use of directional terms is used to describe and understand the present disclosure, not to limit the present disclosure. In the drawings, units of similar structure are using the same numeral to represent.

Drawings and specific embodiments of the present disclosure are combined for the further description below.

### First Embodiment

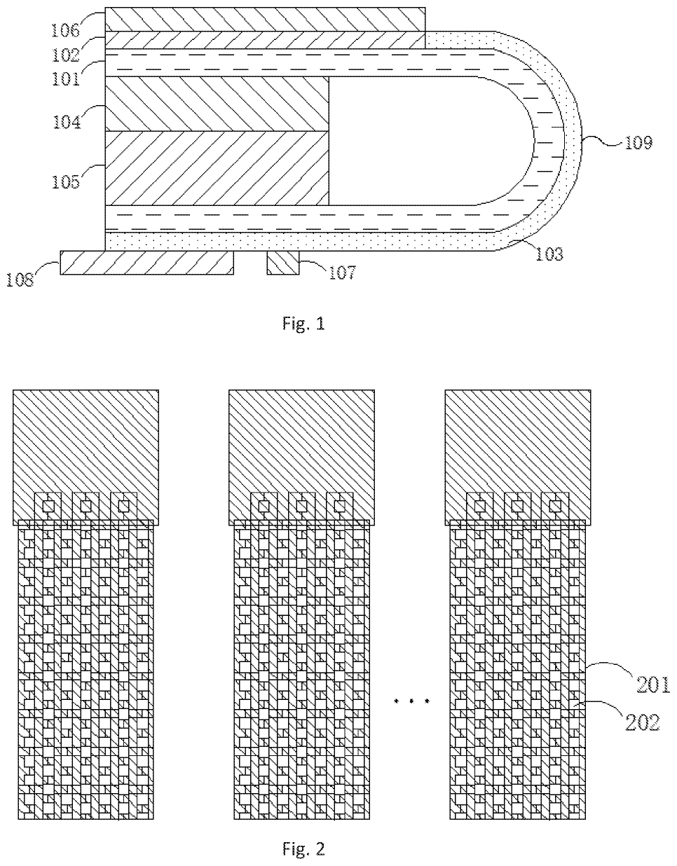

The embodiment of the present disclosure provides a display panel. Combine FIG. 1 and FIG. 2 for the detail description below. As shown in FIG. 1, which is a structural diagram of the display panel 109 provided by the embodiment of the present disclosure, the display panel 109 includes a substrate 101, a display layer 102 and a signal line layer 103. The display layer 102 is disposed on the substrate 101, and the signal line layer 103 is disposed on the substrate 101. The signal line layer 101 includes a plurality of spaced signal lines 201 arranged in parallel.

As shown in FIG. 2, which is a structural diagram of the signal line layer provided by the embodiment of the present disclosure, the signal line 201 has a plurality of columns of through holes 202, and the through holes 202 in neighboring two columns are staggered with each other. Reducing the number of the segments of the signal line 201 can decrease the impedance of the signal line 201 of the display panel 109 effectively and lower the delay of the signal transmission through the signal line 201, thereby improving the display quality of the display panel 109.

Preferably, a shape of each of the through holes 202 is one of a rectangle, a rhombus, a circle, or a combination of different shapes.

Preferably, material of the signal line layer 103 is metal.

Preferably, the display panel 109 further includes a buffer protection layer 104 and a support layer 105. The substrate 101 is made of a flexible material, and polyimide is generally selected as the material of the substrate 101. One end of the signal line layer 103 is connected to the display layer 102, and the other end of the signal line layer 103 and the substrate 101 are bent to the back of the display layer 102. The support layer 105 is disposed on a side of the substrate 101 away from the display layer 102. The buffer protection layer 104 is disposed between the support layer 105 and the side of the substrate 101 near the display layer 102.

Preferably, the display panel 109 further includes a first organic protective layer and a second organic protective layer (not shown in figure). The first organic protective layer is disposed between the substrate 101 and the signal line layer 103. The second organic protective layer is disposed on the signal line layer 103. Organic protective layers protect both side of the signal line layer 103, which is more advantageous for improving the bending durability of the signal line layer 103.

Preferably, the display panel 109 further includes a barrier layer (not shown in figure), and the barrier layer is disposed between the substrate 101 and the first organic protective layer. The barrier layer can be used to block water and oxygen from intruding into the light emitting device and the signal line layer 103, and protects the light emitting device and the signal line layer 103 from water and oxygen.

Preferably, the display panel 109 further includes a driver circuit chip 107 and a flexible circuit board 108, and the driver circuit chip 107 and the flexible circuit board 108 are disposed on the signal line layer. The display panel, the substrate 101 and the signal line layer 103 are bent to the back of the display layer 102, and narrow the width of the bezel of the display panel.

Preferably, the display panel further include a polarizer 106. The polarizer 106 is disposed on the display panel 102.

### Second Embodiment

The embodiment of the present disclosure provides a display device. Combine FIG. 1 and FIG. 2 for the detail description below. The display device includes a display panel 109.

The display panel 109 includes a substrate 101, a display layer 102 and a signal line layer 103. The signal line layer 103 is disposed on the substrate 101. The signal line layer 101 includes a plurality of spaced signal lines 201 arranged in parallel.

As shown in FIG. 2, which is a structural diagram of the signal line layer provided by the embodiment of the present disclosure, the signal line 201 has a plurality of columns of through holes 202, and the through holes 202 in neighboring two columns are staggered with each other. Reducing the number of the segments of the signal line 201 can decrease the impedance of the signal line 201 of the display panel 109 effectively and lower the delay of the signal transmission through the signal line 201, thereby improving the display quality of the display panel 109.

Preferably, a shape of each of the through holes 202 is one of a rectangle, a rhombus, a circle, or a combination of different shapes.

Preferably, material of the signal line layer 103 is metal.

Preferably, the display panel 109 further includes a buffer protection layer 104 and a support layer 105. The substrate 101 is made of a flexible material, and polyimide is generally selected as the material of the substrate 101. One end of the signal line layer 103 is connected to the display layer 102, and the other end of the signal line layer 103 and the substrate 101 are bent to the back of the display layer 102. The support layer 105 is disposed on a side of the substrate 101 away from the display layer 102. The buffer protection layer 104 is disposed between the support layer 105 and the side of the substrate 101 near the display layer 102.

Preferably, the display panel 109 further includes a first organic protective layer and a second organic protective layer (not shown in figure). The first organic protective layer is disposed between the substrate 101 and the signal line layer 103. The second organic protective layer is disposed on the signal line layer 103. Organic protective layers protect both side of the signal line layer 103, which is more advantageous for improving the bending durability of the signal line layer 103.

Preferably, the display panel 109 further includes a barrier layer (not shown in figure), and the barrier layer is disposed between the substrate 101 and the first organic protective layer. The barrier layer can be used to block water and oxygen from intruding into the light emitting device and the signal line layer 103, and protects the light emitting device and the signal line layer 103 from water and oxygen.

Preferably, the display panel 109 further includes a driver circuit chip 107 and a flexible circuit board 108, and the driver circuit chip 107 and the flexible circuit board 108 are disposed on the signal line layer. The display panel, the substrate 101 and the signal line layer 103 are bent to the back of the display layer 102, and narrow the width of the bezel of the display panel.

Preferably, the display panel further include a polarizer 106. The polarizer 106 is disposed on the display panel 102.

### Third Embodiment

The embodiment of the present disclosure provides a display device. Combine FIG. 1 and FIG. 2 for the detail description below. The display device includes a display panel 109.

The display panel 109 includes a substrate 101, a display layer 102 and a signal line layer 103. The signal line layer 103 is disposed on the substrate 101. The signal line layer 101 includes a plurality of spaced signal lines 201 arranged in parallel. In this embodiment, material of the signal line layer 101 is metal.

As shown in FIG. 2, which is a structural diagram of the signal line layer provided by the embodiment of the present disclosure, the signal line 201 has a plurality of columns of through holes 202, and the through holes 202 in neighboring two columns are staggered with each other. Reducing the number of the segments of the signal line 201 can decrease the impedance of the signal line 201 of the display panel 109 effectively and lower the delay of the signal transmission through the signal line 201, thereby improving the display quality of the display panel 109.

In this embodiment, the display panel 109 further includes a buffer protection layer 104 and a support layer 105. The substrate 101 is made of a flexible material, and polyimide is generally selected as the material of the substrate 101. One end of the signal line layer 103 is connected to the display layer 102, and the other end of the signal line layer 103 and the substrate 101 are bent to the back of the display layer 102. The support layer 105 is disposed on a side of the substrate 101 away from the display layer 102.

Preferably, the buffer protection layer 104 is disposed between the support layer 105 and the side of the substrate 101 near the display layer 102.

Preferably, a shape of each of the through holes 202 is one of a rectangle, a rhombus, a circle, or a combination of different shapes.

Preferably, the display panel 109 further includes a first organic protective layer and a second organic protective layer (not shown in figure). The first organic protective layer is disposed between the substrate 101 and the signal line layer 103. The second organic protective layer is disposed on the signal line layer 103. Organic protective layers protect both side of the signal line layer 103, which is more advantageous for improving the bending durability of the signal line layer 103.

Preferably, the display panel 109 further includes a barrier layer (not shown in figure), and the barrier layer is disposed between the substrate 101 and the first organic protective layer. The barrier layer can be used to block water and oxygen from intruding into the light emitting device and the signal line layer 103, and protects the light emitting device and the signal line layer 103 from water and oxygen.

Preferably, the display panel 109 further includes a driver circuit chip 107 and a flexible circuit board 108, and the driver circuit chip 107 and the flexible circuit board 108 are disposed on the signal line layer. The display panel, the substrate 101 and the signal line layer 103 are bent to the back of the display layer 102, and narrow the width of the bezel of the display panel.

Preferably, the display panel further include a polarizer 106. The polarizer 106 is disposed on the display panel 102.

The present embodiments of the disclosure show that there has a plurality of columns of through holes are disposed on the signal line of the signal line layer of the display panel, and the through holes in neighboring two columns are staggered with each other. Reducing the number of the segments of the signal line can decrease the impedance of the signal line of the signal line layer of the display panel effectively and lower the delay of the signal transmission through the signal line of the signal line layer, thereby improving the display quality of the display panel.

Although the present invention has been disclosed above by the preferred embodiments, the preferred embodiments are not intended to limit the invention. One of ordinary skill in the art, without departing from the spirit and scope of the present invention, can make various modifications and variations of the present invention. Therefore, the scope of the claims to define the scope of equivalents.

What is claimed is:

1. A display panel, comprising:
a substrate;
a display layer, the display layer disposed on the substrate; and
a signal line layer, the signal line layer disposed on the substrate;
wherein the signal line layer comprises a plurality of spaced signal lines, each of the signal lines has a plurality of columns of through holes, and the through holes in neighboring two columns are staggered with each other.

2. The display panel as claimed in claim 1, wherein a shape of each of the through holes is a rectangle, a rhombus, or a circle.

3. The display panel as claimed in claim 1, wherein material of the signal line layer is metal.

4. The display panel as claimed in claim 1, wherein the display panel comprises a buffer protection layer and a support layer;
wherein the substrate and the signal line layer are bent to the back of the display layer;
wherein the support layer is disposed on a side of the substrate away from the display layer; and
wherein the buffer protection layer is disposed between the support layer and the side of the substrate near the display layer.

5. The display panel as claimed in claim 4, wherein the display panel comprises a first organic protective layer and a second organic protective layer;
wherein the first organic protective layer is disposed between the substrate and the signal line layer; and
wherein the second organic protective layer is disposed on the signal line layer.

6. The display panel as claimed in claim 5, wherein the display panel comprises a barrier layer, and the barrier layer is disposed between the substrate and the first organic protective layer.

7. The display panel as claimed in claim 6, wherein the display panel comprises a driver circuit chip and a flexible circuit board, and the driver circuit chip and the flexible circuit board are disposed on the signal line layer.

8. A display device, comprising:
a display panel, the display panel comprising a substrate, a display layer, and a signal line layer;
wherein the display layer and the signal line layer are disposed on the substrate; and
wherein the signal line layer comprises a plurality of spaced signal lines, each of the signal lines has a plurality of columns of through holes, and the through holes in neighboring two columns are staggered with each other.

9. The display device as claimed in claim 8, wherein material of the signal line layer is a metal.

10. The display device as claimed in claim 8, wherein a shape of each of the through holes is a rectangle, a rhombus, or a circle.

11. The display device as claimed in claim 8, wherein the display panel comprises a buffer protection layer and a support layer;
wherein the substrate and the signal line layer are bent to the back of the display layer;
wherein the support layer is disposed on a side of the substrate away from the display layer; and
wherein the buffer protection layer is disposed between the support layer and the side of the substrate near the display layer.

12. The display device as claimed in claim 11, wherein the display panel comprises a first organic protective layer and a second organic protective layer;
wherein the first organic protective layer is disposed between the substrate and the signal line layer; and
wherein the second organic protective layer is disposed on the signal line layer.

13. The display device as claimed in claim 12, wherein the display panel comprises a barrier layer, and the barrier layer is disposed between the substrate and the first organic protective layer.

14. The display device as claimed in claim 13, wherein the display panel comprises a driver circuit chip and a flexible circuit board, and the driver circuit chip and the flexible circuit board are disposed on the signal line layer.

15. A display device, comprising:
a display panel, the display panel comprising a substrate, a display layer, and a signal line layer;
wherein the display layer and the signal line layer are disposed on the substrate;
wherein the support layer is disposed on a side of the substrate away from the display layer;
wherein the substrate and the signal line layer are bent to the back of the display layer;
wherein material of the signal line layer is metal; and
wherein the signal line layer comprises a plurality of spaced signal lines, each of the signal lines has a plurality of columns of through holes, and the through holes in neighboring two columns are staggered with each other.

16. The display device as claimed in claim 15, wherein a shape of each of the through holes is a rectangle, a rhombus, or a circle.

17. The display device as claimed in claim 15, wherein the display panel comprises a first organic protective layer and a second organic protective layer;
wherein the first organic protective layer is disposed between the substrate and the signal line layer; and
wherein the second organic protective layer is disposed on the signal line layer.

18. The display device as claimed in claim 17, wherein the display panel comprises a barrier layer, and the barrier layer is disposed between the substrate and the first organic protective layer.

19. The display device as claimed in claim 18, wherein the display panel comprises a driver circuit chip and a flexible circuit board, and the driver circuit chip and the flexible circuit board are disposed on the signal line layer.
